(19) United States
(12) Patent Application Publication
(10) Pub. No.: US 2024/0243586 A1
(43) Pub. Date: Jul. 18, 2024

(54) Photovoltaic Module

(71) Applicant: Solaredge Technologies Ltd., Herzeliya (IL)

(72) Inventors: Liron Har-Shai, Tel Mond (IL); Alon Zohar, Netanya (IL)

(21) Appl. No.: 18/621,500

(22) Filed: Mar. 29, 2024

Related U.S. Application Data
(63) Continuation of application No. 17/126,829, filed on Dec. 18, 2020, now Pat. No. 11,979,037.
Application No. 17/126,829 is a continuation of application No. 13/738,533, filed on Jan. 10, 2013, now Pat. No. 10,931,119.

(30) Foreign Application Priority Data
Jan. 11, 2012 (GB) 1200423.0

(51) Int. Cl. H02J 7/00; H01L 31/02

(52) U.S. Cl. CPC H02J 7/00; H01L 31/02021; Y02E 10/50

(57) ABSTRACT

A photovoltaic module including a photovoltaic panel and an electrical circuit connected thereto. The photovoltaic panel may include multiple bus bars connected to an input of the electrical circuit. The electrical circuit may include at least one input bypass circuit connected across the bus bars at the input of the electrical circuit. Circuitry may include a switch connected between the input and the output of the electrical circuit. The circuitry may function to disconnect the photovoltaic panel from the output of the electrical circuit. An output bypass circuit is connected to the output of the electrical circuit. The output of the electrical circuit is connectible to a second like electrical circuit of a second like photovoltaic module. The output bypass circuit may be an active bypass circuit which draws power from the output of the electrical circuit.

### CROSS-REFERENCE TO RELATED APPLICATIONS

This application is a continuation of U.S. application Ser. No. 17/126,829, filed Dec. 18, 2020, which is a continuation of U.S. application Ser. No. 13/738,533, now U.S. Pat. No. 10,931,119, which claims priority to GB Application No. 1200423.0, filed Jan. 11, 2012, the disclosures of which are hereby incorporated by reference in their entireties.

### BACKGROUND

### 1. Technical Field

Aspects of the present disclosure relate to distributed power systems, particularly a photovoltaic module including an electrical circuit connected to or connectible to a photovoltaic panel.

### 2. Description of Related Art

Photovoltaic panels include inter-connected photovoltaic cells which produce electrical current when solar radiation is absorbed. When part of a photovoltaic panel is shaded, some of the shaded photovoltaic cells within the photovoltaic panel may not be able to produce as much current as the unshaded photovoltaic cells. Since photovoltaic cells may be connected in series, substantially the same current flows through every series- connected photovoltaic cell by virtue of Kirchhoff's current law. The unshaded photovoltaic cells may force the shaded photovoltaic cells to pass more current. The shaded photovoltaic cells may operate at a current higher than their short circuit current and at a negative voltage which may cause an overall net voltage loss from the photovoltaic panel. The current flowing in the series connection of photovoltaic cells multiplied by the negative voltage results in a negative power produced by the shaded photovoltaic cells. In other words, the shaded photovoltaic cells dissipate power as heat and cause “hot spots” in the photovoltaic panel. The shaded photovoltaic cells may then drag down the overall current/voltage (I/V) curve of the group of photovoltaic cells.

The effect of shading may also be dependent on how the photovoltaic panel is shaded. It may be far worse to shade one photovoltaic cell 75% than to shade three photovoltaic cells 25% each. One way to minimize the effect of shading is to create multiple photovoltaic sub-strings of photovoltaic cells connected in a series string and to use bypass diodes across each photovoltaic sub-string. Bypass diodes may allow current to pass around shaded photovoltaic sub-strings of photovoltaic cells and thereby reduce the voltage losses through the string. When a photovoltaic sub-string becomes shaded its bypass diode becomes “forward biased” and begins to conduct current. Current greater than the short circuit current of the shaded photovoltaic sub-string is “bypassed” through the bypass diode, thus reducing the amount of local heating at the shaded area.

Bus ribbon or bus bar may provide connections between photovoltaic cells within the photovoltaic panel. The sub-strings of the photovoltaic panel are connectible externally for instance to the bypass diodes by bus ribbon at the back side of a photovoltaic panel. Bus ribbon may be copper ribbon, or flat wire, that is coated in solder. The solder protects the surface of the copper from oxidation and provides a layer of solder to form the solder joint. Bus ribbon is generally 5mm-6 mm wide, although some applications require bus ribbon to be more than twice as wide.

Bus ribbon or bus bar may serve as an input or output to a junction box which may be mounted on the back side of the photovoltaic panel. A bus bar is a strip of copper or aluminum that may conduct electricity within the junction box and allows connections to be made to other bus bars, bus ribbons, wires, terminals or tabs. The junction box also allows for mechanical support of connections made to other bus bars, bus ribbons, wires, terminals or tabs as well as electrical isolation/insulation.

### BRIEF SUMMARY

Various electrically circuits optionally mountable in a junction box are provided for a photovoltaic panel. The photovoltaic panel may include a photovoltaic sub-string of serially connected photovoltaic cells. The photovoltaic sub-string may output to multiple bus bars at the photovoltaic panel output. The electrical circuit includes an input bypass circuit connected across the bus bars. The input bypass circuit may be configured to provide a low impedance current path to the photovoltaic sub-string when the photovoltaic cells of the photovoltaic sub-string may be substantially in reverse bias. The electrical circuit may have circuitry with one or more inputs which may be connected to the bus bars and an output which may be operatively connectible in series to a photovoltaic string. The circuitry may also include a switch for either connecting or disconnecting the photovoltaic panel from the photovoltaic string. An output bypass circuit may be connected across the output of the circuitry. The output bypass circuit may operate to pass current of the photovoltaic string when the switch disconnects the photovoltaic panel from the photovoltaic string. The input bypass circuit may include at least one passive bypass diode connected across the bus bars which may be operable to provide the low impedance path when the photovoltaic sub-string substantially sinks current. The input bypass circuit may include an active solid state switch configured to draw operating power from the photovoltaic panel.

The photovoltaic string may include serially connected like electrical circuits at respective outputs of the electrical circuits. The electrical circuits may be configured to connect multiple photovoltaic panels at respective inputs of the electrical circuites. The output bypass circuit may include an active solid state switch which may be operable by drawing current from the photovoltaic string when the photovoltaic panel may be disconnected from the photovoltaic string. The output bypass circuit may further include a transistor, with a source and a drain connectible to the photovoltaic string and a gate which is controllable using power from the string. The output bypass circuit may also include a charge storage device connectible across the output of the circuitry. The charge storage device may be operable to provide operating power for the output bypass circuit from current through the photovoltaic string. The charge storage device may be charged during a short period of time and discharged during a longer period of time which may be greater than the short period of time. With a current flowing in the photovoltaic string, the charge storage device may be charged and discharged regardless of whether the output bypass circuit may be providing a bypass or not providing a bypass. The short period of time may be between 5 milliseconds and 15 milliseconds. The long period of time may be between 5 seconds and 15 seconds.

Other aspects of the present invention may include a photovoltaic module including a photovoltaic panel and an electrical circuit connectible thereto. The photovoltaic panel may include multiple bus bars connected to an input of the electrical circuit. The electrical circuit may include at least one input bypass circuit connected across the bus bars at the input of the electrical circuit. The electrical circuit may include a switch connected between the input and the output of the electrical circuit. The circuit may function to disconnect the photovoltaic panel from the output of the electrical circuit. An output bypass circuit is connected to the output of the electrical circuit. The output of the electrical circuit is connectible to a second like electrical circuit of a second like photovoltaic module. The output bypass circuit may be an active bypass circuit which draws power from the output of the electrical circuit and functions to bypass current of the second electrical circuit through the output when the photovoltaic panel is disconnected. The first and second electrical circuites may be connectible at the respective outputs to form a photovoltaic string. The output bypass circuit may be an active circuit which draws power from the photovoltaic string when the photovoltaic panel is disconnected from the photovoltaic string.

The photovoltaic panel and the electrical circuit or junction box mounting the electrical circuit may be permanently attached to each other.

Yet other embodiments include a circuit for an output bypass circuit. The output bypass circuit may include a positive terminal and a negative terminal. The circuit has a first transistor, e.g metal oxide field effect transistor (MOSFET) with a first gate, a first drain and a first source and a first integral diode. A first anode and a first cathode of the first integral diode may be connectable respectively to the first drain and the first source. The first drain is the cathode of the circuit. The circuit may also have a second transistor, e.g metal oxide field effect transistor MOSFET with a second gate terminal, a second drain and a second source. The second source connects to the first source. The second drain is the positive terminal of the circuit. A controller may be adapted to connect to the first gate terminal and the second gate terminal. The controller may be configured to cause a switching of the first MOSFET and the second MOSFET. A charge storage device input may be connected across the second drain and the second source. A current flowing between the positive and negative terminals of the circuit may charge the charge storage device based on the switching. An output of the charge storage device may provide a source of direct current (DC) power to the controller by a discharge of the charge storage device based on the switching. The charge storage device may further include a zener diode with a cathode connected to the second drain and an anode connected to the second source. A diode with an anode connected to the second drain and a cathode connected to one end of a capacitor and the other end of the capacitor connected to the second source.

### BRIEF DESCRIPTION OF THE DRAWINGS

Certain embodiments are illustrated by way of example, and not by way of limitation, in the accompanying figures, wherein like reference numerals refer to the like elements throughout:

FIG. 1a shows a photovoltaic panel, according to a feature of the present invention.

FIG. 1b shows a power harvesting system, according to a feature of the present invention.

FIG. 1c shows more details of a junction box including an electrical circuit according to a feature of the present invention.

FIG. 1d shows more details of a bypass circuit according to an exemplary feature of the present invention.

FIG. 1e shows a timing diagram for the bypass circuit shown in FIG. 1c.

FIG. 1f shows another alternative circuit feature for the electrical circuit shown in FIG. 1c.

### DETAILED DESCRIPTION

Reference will now be made in detail to features of the present invention, examples of which are illustrated in the accompanying drawings, wherein like reference numerals refer to the like elements throughout. The features are described below to explain the present invention by referring to the figures.

Before explaining features of the invention in detail, it is to be understood that the invention is not limited in its application to the details of design and the arrangement of the components set forth in the following description or illustrated in the drawings. The invention is capable of other features or of being practiced or carried out in various ways.

Also, it is to be understood that the phraseology and terminology employed herein is for the purpose of description and should not be regarded as limiting. For example, the indefinite articles “a”, “an” is used herein, such as “a switch”, “a bypass” have the meaning of “one or more” that is “one or more switches” or “one or more bypasses”. The terms “bus bar”, “bus ribbon”, “wires”, ‘terminals” or “tabs” are used herein interchangeably.

The term “field effect transistor” (FET) as used herein refers to any FET device such as a metal oxide semiconductor field effect transistor. According to features of the present invention, bipolar transistors may be equivalently used to replace FET devices.

The term “switch” as used herein refers to any of but not limited to: silicon controlled rectifier (SCR), insulated gate bipolar junction transistor (IGBT), bipolar junction transistor (BJT), field effect transistor (FET), junction field effect transistor (JFET), mechanically operated single pole double pole switch (SPDT), SPDT electrical relay, SPDT reed relay, SPDT solid state relay, insulated gate field effect transistor (IGFET), diode for alternating current (DIAC), triode for alternating current (TRIAC) and a mechanical switch.

The term “photovoltaic module” as used herein refers a photovoltaic panel connected electrically and/or mechanically attached to an electrical circuit.

The term “photovoltaic string” as used herein refers to multiple photovoltaic modules respective outputs connected electrically in series to form the photovoltaic string.

The term “photovoltaic sub-string” as used herein refers to a number of serial connected photovoltaic cells within a photovoltaic string.

The term “bus bar” as used herein refers to an electrical termination provided from a photovoltaic panel. The bus bar typically continues as a strip of copper or aluminum within an electrical circuit (attached to the photovoltaic panel) that may conduct electricity and allows connections to be made to other bus bars, bus ribbons, wires, terminals, tabs and other circuitry within the junction box. The terms “bus bar”, “bus ribbon”, “wires”, “terminals” or “tabs” are used herein interchangeably.

The term “bypass” as used herein refers to a low-resistance connection between two points in an electric circuit that forms an alternative path for a portion of the current.

The term “passive” device as used herein, refers to the “passive” device not requiring external power from a source of power to perform a circuit function.

The term “active” device as used herein, refers to the “active” device which requires power from an external source of power to perform a circuit function.

The term “operable” as used herein with reference to an active solid state switch, e.g. a field effect transistor (FET) refers to a controllable and variable voltage or current applied to a control terminal, e.g. gate, of the switch which determines how much current is allowed to flow between the source and drain of the FET.

It should be noted, that although the discussion herein relates primarily to photovoltaic systems, the present invention may by non-limiting example, alternatively be configured using other distributed power systems including (but not limited to) wind turbines, hydro turbines, fuel cells, storage systems such as battery, super-conducting flywheel, and capacitors, and mechanical devices including conventional and variable speed diesel engines, Stirling engines, gas turbines, and micro-turbines.

By way of introduction, aspects of the present disclosure are directed to reduce the power loss incurred with use of conventional input bypass diodes and to provide a low loss bypass circuit when the photovoltaic panel is disconnected from the string. An electrical circuit with an active bypass of the input and/or output of the electrical circuit is provided by use of bypass circuits. The input of the electrical circuit may be connected to the output of a direct current (DC) power source such as a photovoltaic panel. The output of the electrical circuit may be connected in a series string of other DC outputs and/or DC sources. The photovoltaic string may be connected across a load, e.g. inverter.

One of the purposes of a junction box attached to a photovoltaic panel is to provide electrical termination of ribbon cables, bus bars or cabling entering the junction box via cable glands.

According to an exemplary embodiment, the photovoltaic module includes an electrical circuit connected at its input to a photovoltaic panel. The electrical circuit includes an input bypass circuit and an output bypass circuit. The input and/or output bypass circuits when activated may provide a lower impedance when compared with forward biased semi-conductor diodes used conventionally for the same purpose. The lower impedance may allow for less power dissipation by the bypass circuits when compared with the forward biased semi-conductor diodes. The output of the electrical circuit may be connected in series with like photovoltaic modules. The output bypass circuit may receive power from the series string of similar DC outputs, if for example the photovoltaic panel is disconnected from the string and power is consequently not available from the photovoltaic panel. The lower power dissipation by the bypass circuit may provide lower heat dissipation thereby reducing potential problems related to heat generation within the electrical circuit. The lower power dissipation by the bypass circuit compared with semi-conductor bypass diodes may reduce the complexity, size and material of the junction box.

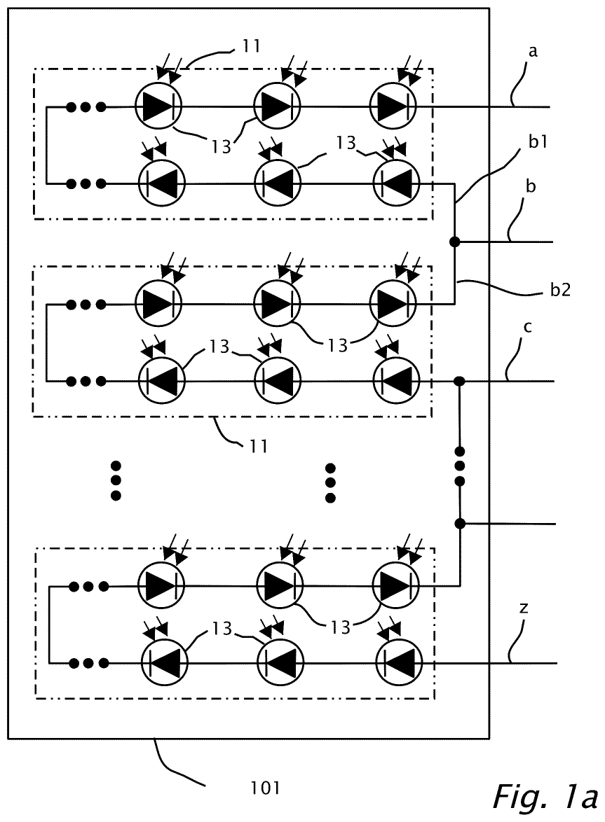

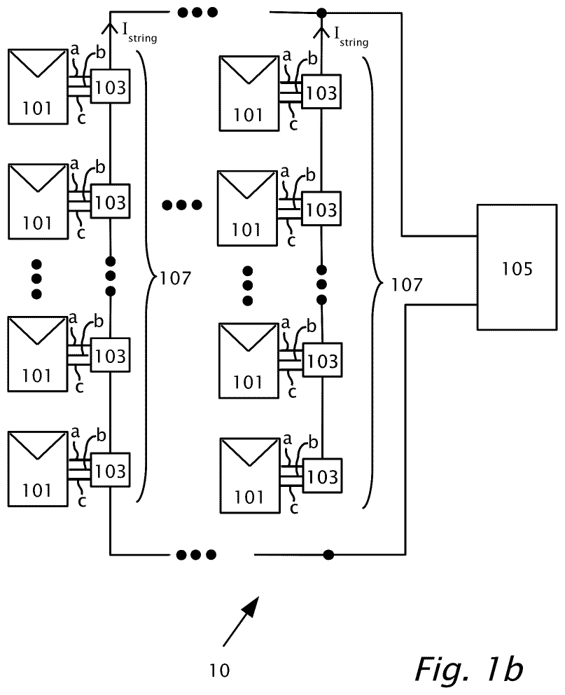

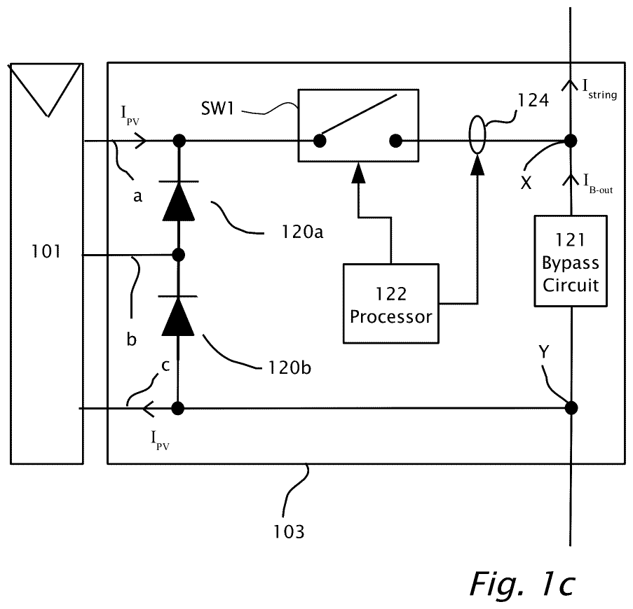

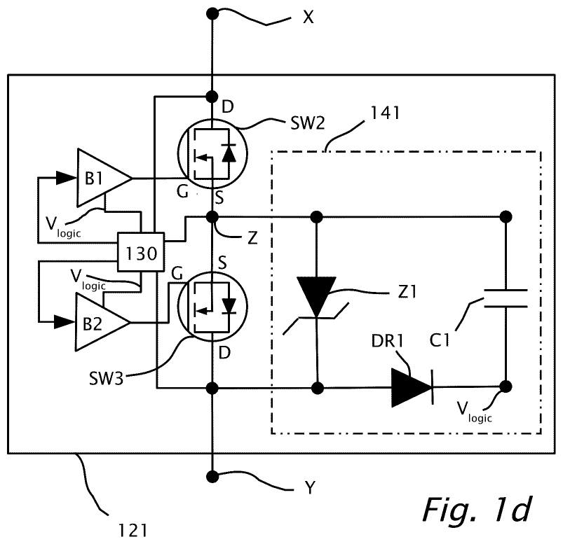

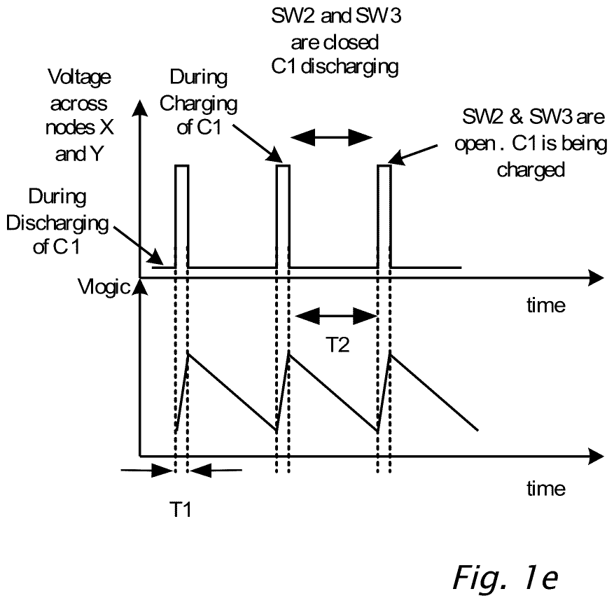

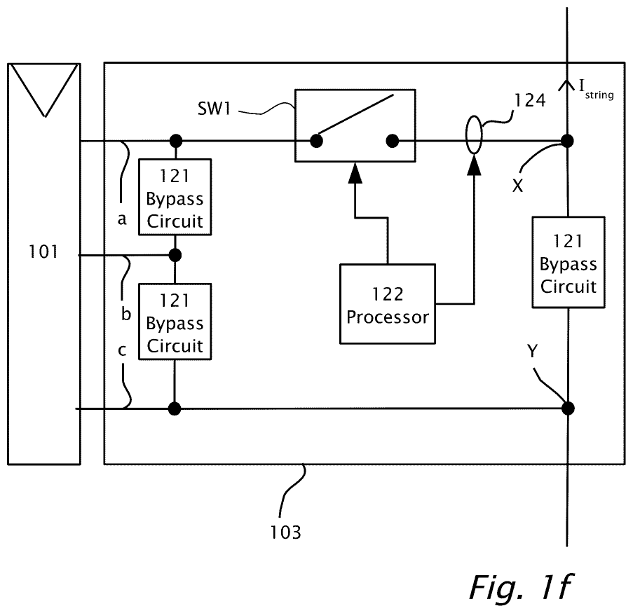

Reference is now made to FIG. 1a which shows a photovoltaic panel 101, according to a feature of the present invention. Panel 101 shows multiple serially connected sub-strings. Each photovoltaic sub-string 11 may include a series connection of multiple photovoltaic cells 13. Bus bars a-z provide connections to the series connections between sub-strings 11. Alternatively, each photovoltaic sub-string 11 may include series-parallel or parallel-series connections between photovoltaic cells 13. Sub-strings 11 may also be connected in various series-parallel or parallel-series combinations by virtue of connections b1 and b2 being made available outside panel 101 as separate bus bars instead of being internally connected inside panel 101 to give bus bar b as shown in FIG. 1a.

Reference is also now made to FIG. 1b which shows a power harvesting system 10, according to a feature of the present invention. Power harvesting system 10 includes multiple photovoltaic panels 101, load 105, multiple electrical circuits 103 each with bus-bars a, b and c. According to an example of the feature, a photovoltaic panel 101 includes two sub-strings 11 of serially connected photovoltaic cells 13 and three bus bars a, b and c. Circuit 103 provides electrical terminations, mechanical support of bus bars a, b and c as an input to electrical circuit 103. Electrical circuit 103 may be attachable and/or re-attachable to panel 101 or may be permanently attachable to panel 101 using for example a thermoset adhesive, e.g. an epoxy adhesive. The electrical outputs of electrical circuits 103 may be connected in series to form a series photovoltaic string 107 through which a string current (I_{string}) may flow. Multiple photovoltaic strings 107 may be connected in parallel and across an input of a load 105. Load 105 may be a direct current (DC) load such as a DC motor, a battery, an input to a DC to DC converter or an input to a DC to AC inverter.

Reference is now made to FIG. 1c which shows more details of electrical circuit 103 shown in FIG. 1b according to a feature of the present invention. Bus bars a, b and c are input to electrical circuit 103 from panel 101. The input has two bypass diodes 120a and 120b with anodes connected to bus bars c and b respectively and cathodes connected to bus bars a and b respectively. A single pole switch SW1 may connect serially between the cathode of diode 120a and node X. Switch SW1 may alternatively be connected between the anode of diode 120b and node Y. The control of switch SW1 is operatively attached to processor 122. Switch SW1 may be opened and closed by processor 122 based for example on the current flowing through switch SW1 or the voltage at node X via sensor 124. Switch SW1 may be part of a power converter, e.g. a DC to DC converter such as a buck circuit, a boost circuit or buck plus boost circuit. A bypass circuit 121 is connected across nodes X and Y connecting serial photovoltaic string 107.

During normal operation of power harvesting system 10, panels 101 are irradiated by the Sun, panel 101 current (I_{PV}) is substantially equal to the string current (I_{string}), switch SW1 is closed and current (I_{B-out}) through output bypass circuit 121 is substantially zero. The maximum string current (I_{string}) is normally limited by the worst performing panel 101 in a photovoltaic string 107 by virtue of Kirchoff's current law.

In a panel 101, if certain photovoltaic cells 13 are shaded, the current passing through the shaded cells 13 may be offered an alternative, parallel path through the inactive cells 13, and the integrity of the shaded cells 13 may be preserved. The purpose of diodes 120a and 120b is to draw the current away from the shaded or damaged cells 13 associated with diodes 120a and 120b in respective sub-strings 11. Bypass diodes 120a and 120b become forward biased when their associated shadowed cells 13 become reverse biased. Since the photovoltaic cells 13 and the associated bypass diodes 120a and 120b are in parallel, rather than forcing current through the shadowed cells 13, the bypass diodes 120a and 120b draw the current away from the shadowed cells 13 and completes the electrical current to maintain the connection to the next cells 13 in a photovoltaic sub-string 11.

Processor 122 may be programmed under certain circumstances based on previously determined criteria, for instance based on current and voltage sensed on sensor 124, to open switch SW1, and thereby disconnect panel 101 from serial photovoltaic string 107. Bypass circuit 121 is configured to provide a low impedance path such that the output bypass current (I_{B-out}) of bypass circuit 121 is substantially equal to photovoltaic string 107 current (I_{string}).

Reference is now made to FIG. 1d which shows more details of an active bypass circuit 121 according to an exemplary feature of the present invention. Bypass circuit 121 includes switches SW2 and SW3 (operatively attached to a controller 130) and a charging circuit 141. Switches SW2 and SW3 in the example are implemented using metal oxide semiconductor field effect transistors (MOSFETs). Alternative solid state switches may be used for switches SW2 and SW3. The drain (D) of switch SW2 connects to node X. The source (S) of switch SW2 connects to the source (S) of switch SW3. An integral diode of switch SW2 has an anode connected to the source (S) of switch SW2 and a cathode connected to the drain (D) of switch SW2. The drain (D) of switch SW3 connects to node Y. Switch SW3 may have an integral diode with an anode connected to the source (S) of switch SW3 and a cathode connected to the drain (D) of switch SW3. Controller 130 connects to and senses node Z where the source of switch SW2 connects to the source (S) of switch SW3, connects to and senses node X and also connects to and senses node Y the drain (D) of switch SW3. Controller 130 provides the direct current (DC) voltage (V_{logic}) required by buffer drivers B1 and B2. Buffer drivers B1 and B2 ensure sufficient power is available to turn switches SW2 and SW3 on and off. The outputs of buffer drivers B1 and B2 are connected to the gates (G) of switches SW2 and SW3 respectively. Buffer drivers B1 and B2 receive their respective inputs from controller 130. Charging circuit 141 has an input which connects to node Y and to node Z. Connected to node Z is the anode of a zener diode Z1. The cathode of zener diode Z1 connects to node Y. Zener diode Z1 may be alternatively implemented as a transient voltage suppression (TVS) diode. A charge storage device C1 has one end connected to the cathode of diode rectifier DR1 and the other end of charge storage device C1 connected to node Z. The anode of diode rectifier DR1 connects to node Y. Charge storage C1 device may be a capacitor, a battery or any device known in the art for storing electric charge. The end of capacitor C1 connected to the cathode of diode rectifier DR1 provides the DC voltage (V_{logic}) to controller 130 and buffer drivers B1 and B2.

During the normal operation of power harvesting system 10 where panels 101 are irradiated, the output of an electrical circuit 103 may need not be bypassed by bypass circuit 121. Bypass circuit 121 does not bypass by virtue of switches SW2 and SW3 both being off. Switches SW2 and SW3 both being off means substantially no current between respective drains and sources of switches SW2 and SW3 because the respective gates (G) of switches SW2 and SW3 are not been driven by buffer drivers B1 and B2.

A bypass mode of operation of bypass circuit 121 may be when a panel 101 is partially shaded. The bypass mode of operation of circuit 121 may also be just before the normal operation when it still too dark to obtain a significant power output from panels 101, circuit 121 may have no power to work. Making reference now to a timing diagram for circuit 121 operation shown in FIG. 1e. As soon as sufficient light irradiates panels 101 and current flows in photovoltaic string 107, zener diode Z1 has voltage drop VZ1 which charges capacitor C1 so as to provide V_{logic} to controller 130. When capacitor C1 is being charged during time T1, the voltage drop of the output across nodes X and Y is the voltage (VZ1) of zener Z1 plus the voltage across the integral diode of switch SW2.

When V_{logic} is sufficient, all the active circuitry in controller 130 starts to work which closes switches SW2 and SW3 for a time period T2. Time period T2 is much greater than time period T1. Switches SW2 and SW3 being closed (during time T2) gives a voltage drop across nodes X and Y which may be lower than the voltage drop across nodes X and Y during time T1. Therefore, with the longer time period T2 and the voltage drop across nodes X and Y, overall during time T1 plus T2, less power may be lost by bypass circuit 121. Controller 130 continues to work until the voltage (V_{logic}) of charge storage device C1 drops below a minimal voltage and once again charge storage device C1 has voltage drop VZ1 from zener Z1 which charges capacitor C1 so as to provide V_{logic} which powers controller 130 and buffer drivers B1 and B2. Once sufficient power is generated from panels 101, controller can get a voltage supply from a panel 101 at nodes X and Y. Controller 130 may also further receive an external enable in order to work in synchronization with all the other bypass circuits 121 in a photovoltaic string 107.

By virtue of the analog inputs of controller 130 to the source (S) and drain (D) of switches SW2 and SW3 respectively and the source (S) of switch SW3, controller 130 is able to sense if an open circuit or a reverse voltage polarity exists across nodes X and Y. The open circuit sensed on nodes X and Y may indicate that switch SW1 is open and/or a photovoltaic sub-string 11 is open circuit. The reverse polarity across nodes X and Y may indicate that a panel 101 is shaded or faulty or that the panel 101 is operating as a sink of current rather than as a source of current.

During the bypass mode, controller 130 is able to sense on nodes X and Y if a panel 101 is functioning again and so controller 130 removes the bypass. The bypass across nodes X and Y is removed by turning switches SW2 and SW3 off.

Reference is now made to FIG. 1f which shows another alternative circuit feature for electrical circuit 103. The circuit shown in FIG. 1e is the same as FIG. 1c except bypass diodes 120a and 120b are replaced by two bypass circuits 121.

Bus bars a, b and c are input to electrical circuit 103 from panel 101. The input has two bypass circuits 121 with anodes connected to bus bars a, b and c as previously shown in FIG. 1c. Input bypass circuits 121 may include active solid state switch configured to draw operating power from photovoltaic panel 101. A single pole switch SW1 connects serially between photovoltaic panel 101 and output at node X. An output bypass circuit 121 is connected across output nodes X and Y connecting serial photovoltaic string 107.

Although selected features of the present invention have been shown and described, it is to be understood the present invention is not limited to the described features. Instead, it is to be appreciated that changes may be made to these features without departing from the principles and spirit of the invention, the scope of which is defined by the claims and the equivalents thereof.

1. A circuit comprising:
a first node, a second node, and a third node;
a first switch connected between the first node and the second node;
a second switch connected between the second node and the third node;
a voltage-stabilizing diode connected between the second node and the third node;
a charge storage device connected to the second node; and
a second diode connected between the third node and the charge storage device.

2. The circuit of claim 1, wherein the voltage-stabilizing diode is a zener diode.

3. The circuit of claim 1, wherein the voltage-stabilizing diode is a transient voltage suppression (TVS) diode.

4. The circuit of claim 1, wherein the charge storage device comprises a capacitor.

5. The circuit of claim 1, further comprising a third diode connected between the first node and the second node, and a fourth diode connected between the second node and the third node.

6. The circuit of claim 5, wherein the third diode is an integral diode of the first switch, and the fourth diode is an integral diode of the second switch.

7. The circuit of claim 1, wherein the first switch and the second switch are metal oxide semiconductor field effect transistors.

8. The circuit of claim 1, wherein a source of the first switch is connected to a source of the second switch.

9. The circuit of claim 1, further comprising a controller connected to the third node.

10. The circuit of claim 9, further comprising a first buffer driver and a second buffer driver, wherein the first buffer driver and the second buffer driver are connected to the controller, and wherein the first buffer driver is connected to a gate of the first switch, and the second buffer driver is connected to a gate of the second switch.

11. The circuit of claim 1, further comprising a third switch connected to the first node.

12. The circuit of claim 11, wherein the third switch is connected between the first node and a first photovoltaic panel.

13. The circuit of claim 12, wherein at least one of the first node or the third node is connected to a series string of photovoltaic panels, wherein the series string comprises the first photovoltaic panel and a second photovoltaic panel.

14. A method comprising:
connecting a first switch between a first node and a second node;
connecting a second switch between the second node and a third node;
connecting a voltage-stabilizing diode between the second node and the third node;
connecting a charge storage device to the second node; and
connecting a second diode between the third node and the charge storage device.

15. The method of claim 14, wherein the voltage-stabilizing diode is a zener diode or a transient voltage suppression (TVS) diode.

16. The method of claim 14, wherein the charge storage device comprises a capacitor.

17. The method of claim 14, further comprising connecting a third diode between the first node and the second node, and connecting a fourth diode between the second node and the third node.

18. The method of claim 17, wherein the third diode is an integral diode of the first switch, and the fourth diode is an integral diode of the second switch.

19. The method of claim 14, further comprising connecting a source of the first switch to a source of the second switch.

20. A system comprising:
a series string of photovoltaic panels; and
a circuit connected to the series string of photovoltaic panels, the circuit comprising:
a first node, a second node, and a third node;
a first switch connected between the first node and the second node;
a second switch connected between the second node and the third node;
a voltage-stabilizing diode connected between the second node and the third node;
a charge storage device connected to the second node; and
a second diode connected between the third node and the charge storage device,
wherein at least one of the first node or the third node is connected to at least one photovoltaic panel of the series string of photovoltaic panels.
